(19) United States
(12) Patent Application Publication
(10) Pub. No.: US 2004/0042269 A1
(43) Pub. Date: Mar. 4, 2004

(54) Nonvolatile memory apparatus

(75) Inventors: Takayuki Tamura, Higashiyamato (JP); Yoshinori Takase, Tokyo (JP); Shinichi Shuto, Kokubunji (JP); Yasuhiro Nakamura, Tachikawa (JP); Chiaki Kumahara, Kodaira (JP)

Correspondence Address: Miles & Stockbridge P.C., Suite 500, 1751 Pinnacle Drive, McLean, VA, 22102-3833, US

(73) Assignees: Hitachi, Ltd.; Hitachi ULSI Systems Co., Ltd.

(21) Appl. No.: 10/633,582

(22) Filed: Aug. 5, 2003

(30) Foreign Application Priority Data
Aug. 27, 2002 (JP) 2002-246774

(51) Int. Cl. G11C 16/04

(52) U.S. Cl. 365/185.12

(57) ABSTRACT

Disclosed is a nonvolatile memory apparatus in which a nonvolatile memory and a controller are mounted and which realizes improved performance of read/write speeds and improved resistance to a retention error. A nonvolatile memory can store information of two bits or more, and can perform a first reading operation of outputting information read from a nonvolatile memory cell as 1-bit information and a second reading operation of outputting the read information as 2-bit information. A controller performs the first reading operation to read first information from the nonvolatile memory and performs the second reading operation to read second information. The reading speed of the first reading operation is faster than that of the second reading operation. In writing to a first area to be read, by using either a voltage in the upper-limit threshold voltage distribution or a voltage in the lower-limit threshold voltage distribution as a threshold voltage, resistance to a retention error of the first information is improved.

### BACKGROUND OF THE INVENTION

The present invention relates to a nonvolatile memory apparatus having a nonvolatile memory and a controller and to a technique effectively applied to a memory card having, for example, a flash memory as a nonvolatile memory.

There is a nonvolatile memory capable of storing two-bit information in a single nonvolatile memory cell. Japanese Unexamined Patent Publication No. 10(1998)-106276 (U.S. Pat. No. 6,091,640) discloses a nonvolatile memory cell capable of storing 2-bit information or 1-bit information. According to the technique, in the case of storing 2-bit information into a single nonvolatile memory cell, since a threshold voltage distribution is narrowed, a high-precision write mode is used in which the amount of change in threshold voltage of each nonvolatile memory cell, which is varied each time a pulse voltage is applied, is made relatively small. In the case of storing 1-bit information into a single nonvolatile memory cell, a coarse write mode is used in which the amount of change in threshold voltage of each nonvolatile memory cell, which is varied each time the pulse voltage is applied, is made relatively large. Since the number of application times of the pulse voltage in the coarse write mode is smaller than that in the high-precision write mode, in the case of using the coarse write mode, the number of times of verifying writing is smaller. Consequently, the speed of the write operation is increased as a whole. In the case of giving priority to storage density or storage capacity, the high-precision write mode is used and 2-bit information is stored into a nonvolatile memory cell. Alternately, 1-bit information is converted to 2-bit information later and the 2-bit information is stored into a nonvolatile memory cell. Another nonvolatile memory capable of storing multi-value information is disclosed in the domestic re-publication of WO98/01861 (U.S. Pat. No. 6,166,950).

### SUMMARY OF THE INVENTION

Inventors of the present invention have examined a memory card in which a controller and a flash memory are mounted. For example, the flash memory mounted on the memory card is divided into a user data area, an alternative area, an alternative registration table area, and the like. A peculiar physical block address is assigned to each of the areas. Each area is divided into blocks. Each block (sector) is divided into a data portion and a management information portion indicative of validity of the data portion. When an access request is sent from a host, the controller reads management information in the management information portion disposed in a physical block address to be accessed, determines validity of the corresponding data portion, if the data portion is valid, accesses the data portion and, if the data portion is invalid, obtains the physical block address of an alternative data portion from the alternative registration table area. The controller similarly determines validity of the data portion of the address and, if the data portion is valid, accesses the data portion. As described above, to make an access to the memory card faster, it is necessary to shorten management information reading time of the flash memory.

In the case of storing 4-states data into a nonvolatile memory cell, in the reading operation, by sequentially changing the level of determining stored information, 2-bit information per memory cell is obtained. The reading process takes longer time than that in the case of storing binary-state data in a nonvolatile memory cell. For example, in a multi-value flash memory, first access time in the reading operation (time until the first data is read after a read command is input) is much longer than that in the binary flash memory.

To retrieve a block in a flash memory to be accessed for a read/write command from the host (to check whether the block is good or bad) , first, management information is read. In the multi-value flash memory, first access time to read the management information is long, so that time for checking whether a block to be accessed is good or bad is accordingly long. It disturbs improvement in performance of reading/writing speed.

The inventors herein further examined occurrence of data gable (such as retention error) caused by a change with time and the like. In the case of storing information depending on a change in the threshold voltage of a nonvolatile memory cell, if a plurality of kinds of threshold voltage distributions are close to each other, the possibility of occurrence of data gable due to a change with time increases. The inventors herein have found that if the threshold voltage distributions used for storing information can be made apart from each other without changing the properties of a nonvolatile memory cell, resistance to a retention error caused by a change with time or the like in a required data area can be improved.

Further, the inventors herein have examined the case where a write error occurs during writing of data to a flash memory. In this case, to retrieve an alternative area, an operation of reading the nonvolatile memory cell has to be performed. If read data has to be temporarily held in a data buffer in which write data is temporarily held, the alternative area has to be retrieved after the write data has to be saved in a buffer in the controller. In this case, the buffer of the controller does not store the next data until writing of the write data is completed in consideration that the write data is saved in the buffer or an area for saving the write data has to be provided. In the former case, the write rate seen from the host decreases. In the latter case, cost is increased due to increase in the data buffer size.

An object of the invention is to provide a nonvolatile memory apparatus in which a nonvolatile memory and a controller are mounted, with improved performance of read/write speed.

Another object of the invention is to provide a nonvolatile memory apparatus in which a nonvolatile memory and a controller are mounted, with improved resistance to a retention error caused by a change with time in a required storage area.

Further another object of the invention is to provide a nonvolatile memory apparatus in which a nonvolatile memory and a controller are mounted, which does not require to save write data held in a data buffer in the nonvolatile memory at the time of performing an operation of reading a nonvolatile memory cell in order to retrieve an alternative area in the case where a write error occurs during writing of data to the nonvolatile memory.

The above and other objects and novel features of the invention will become apparent from the description of the specification and the appended drawings.

An outline of representative ones of inventions disclosed in the specification will be briefly described as follows.

[1] A nonvolatile memory apparatus according to the invention has a nonvolatile memory and a controller. The nonvolatile memory has a plurality of nonvolatile memory cells and each of the nonvolatile memory cells can be set in an information storing state included in one of four or more kinds of information storing states, for example, set to a threshold voltage included in one of four or more kinds of threshold voltage distributions. The nonvolatile memory can perform a first reading operation of outputting information read from the nonvolatile memory cell in which the threshold voltage is set as information of m bits (m: integer equal to or larger than 1) , for example, 1-bit information and a second reading operation of outputting information read from the nonvolatile memory cell in which the threshold voltage is set as information of n bits (n: integer larger than m), for example, 2-bit information. The controller performs the first reading operation to read first information from the nonvolatile memory and performs the second reading operation to read second information from the nonvolatile memory.

By the above-described means, the number of operations of checking the threshold voltage of a nonvolatile memory cell in the first reading operation of outputting information read from the nonvolatile memory cell in which a threshold voltage included in one of the four or more kinds of threshold voltage distributions is set as 1-bit information is smaller than that in the second reading operation of outputting information read from the nonvolatile memory cell as 2-bit information. Therefore, the reading operation can be performed faster by that amount. By using second information as a second object to be read as information of a data portion and using first information as a first object to be read as management information of the data portion, time required to read the management information at the time of reading/writing from the host can be shortened. Thus, the speed of operation of reading/writing the nonvolatile memory apparatus such as a memory card by the host can be increased.

In the nonvolatile memory, for example, at the time of storing the first information into the nonvolatile memory cell, either the voltage in the upper-limit threshold voltage distribution or the voltage in the lower-limit threshold voltage distribution is used as the threshold voltage of the nonvolatile memory cell. In the first reading operation, it is sufficient to check the threshold voltage of the nonvolatile memory cell by using a voltage between the upper-limit threshold voltage distribution and the lower-limit threshold voltage distribution. According to the technique, a threshold voltage distribution area which is not directly used for storing information is interposed between the threshold voltage distributions used for storing information. Thus, resistance to a retention error caused by a change with time or the like can be improved in a required storage area such as a storage area of the first information. By storing important data in such a required storage area, the reliability of information storage can be improved.

As a concrete mode of the invention, the nonvolatile memory has a memory buffer which can temporarily hold second information read as 2-bit information from each of a plurality of nonvolatile memory cells by the second reading operation, supply the second information to the controller, also hold second information supplied from the controller, and set a nonvolatile memory cell per two bits at a threshold voltage included in one of four kinds of threshold voltage distributions. The first information read as 1-bit information from each of the plurality of nonvolatile memory cells by the first reading operation is output to the controller while bypassing the memory buffer.

With the configuration, at the time of reading 1-bit information, the memory buffer in the nonvolatile memory is not used. Therefore, in the case where a write error occurs at the time of writing data into the nonvolatile memory, while holding write data in the memory buffer in the nonvolatile memory, an alternative can be retrieved by an operation of reading 1-bit information. Therefore, it is unnecessary to perform the process of saving write data from the memory buffer into the buffer in the controller, the process of retrieving an alternative area can be performed promptly when a write error occurs and, moreover, the buffer capacity of the controller can be suppressed.

[2] A nonvolatile memory apparatus according to a more-detailed mode of the invention has a nonvolatile memory and a controller. The nonvolatile memory has a plurality of nonvolatile memory cells each of which can store information of n bits (n: integer of 2 or larger), for example, two or more bits. The nonvolatile memory can perform a first reading operation of outputting information read from the nonvolatile memory cell as information of m bits (m: integer smaller than n) and a second reading operation of outputting information read from the nonvolatile memory cell as 2-bit information. The controller performs the first reading operation to read first information from the nonvolatile memory and performs the second reading operation to read second information from the nonvolatile memory. By the above-described means, the number of operations of checking information stored in a nonvolatile memory cell in the first reading operation of outputting information read from the nonvolatile memory cell as 1-bit information is smaller than that in the second reading operation of outputting information read from the nonvolatile memory cell as 2-bit information. Therefore, the reading operation can be performed faster by that amount. By using second information as a second object to be read as information of a data portion and using first information as a first object to be read as management information of the data portion, time required to read the management information at the time of reading/writing from the host can be shortened. Thus, the speed of operation of reading/writing the nonvolatile memory apparatus such as a memory card by the host can be increased.

The first information includes validity management information indicative of, for example, validity of a storage area of the second information.

For example, at the time of operating the nonvolatile memory in accordance with an instruction from the outside, the controller checks validity of a storage area of the second information on the basis of the validity management information read from the nonvolatile memory by performing the first reading operation and, when it is determined that the storage area is valid, performs the second reading operation to read the second information from the nonvolatile memory.

Further, the controller checks validity of a storage area of the second information on the basis of validity management information read from the nonvolatile memory by performing the first reading operation, when it is determined that the storage area is invalid, checks validity of the storage area of the second information on the basis of the validity management information read from the nonvolatile memory by performing the first reading operation on an alternative area of the storage area of the second information and, when the storage area is valid, performs the second reading operation to read the second information from the alternative area.

As a concrete mode of the invention, the nonvolatile memory cell has a threshold voltage included in one of four or more kinds of threshold voltage distributions according to information to be stored. At the time of storing the first information into the nonvolatile memory cell, the nonvolatile memory uses a predetermined voltage between the threshold voltage distributions as a boundary, sets, as the threshold voltage of the nonvolatile memory, any of threshold voltage distributions of voltages higher than the predetermined voltage or threshold voltage distributions of voltages lower than the predetermined voltage, and compares the predetermined voltage with the threshold voltage of a nonvolatile memory cell in the first reading operation, thereby reading 1-bit information.

In a desirable mode, the threshold voltage of a nonvolatile memory cell in which the first information is stored is a voltage selected from a voltage in an upper-limit threshold voltage distribution and a voltage in a lower-limit threshold voltage distribution. As described above, resistance to a retention error caused by a change with time or the like can be improved in a required storage area such as a storage area of the first information.

As a further another concrete mode of the invention, the controller can output second information read from the nonvolatile memory by the second reading operation to the outside, and the controller can supply the second information input from the outside to the nonvolatile memory. In this case, the nonvolatile memory has a memory buffer which can temporarily store second information read by the second reading operation before the second information is supplied to the controller and can temporarily store second information supplied from the controller before the second information is stored into the nonvolatile memory cell.

The nonvolatile memory outputs first information while bypassing the memory buffer at the time of reading first information by the first reading operation. As described above, when a write error occurs, the process of retrieving an alternative area can be performed promptly and, moreover, the buffer capacity of the controller can be suppressed.

As a further another concrete mode of the invention, the controller has a controller buffer for temporarily holding second information supplied from the outside and temporarily holding second information read from the nonvolatile memory and supplied. The controller supplies data from the controller buffer to the memory buffer, after that, stores the data in the memory buffer to a nonvolatile memory cell and, in parallel with the storing operation, can input another data from the outside into the controller buffer. It can contribute to increase the speed of the writing operation.

### BRIEF DESCRIPTION OF THE DRAWINGS

FIG. 1 is a block diagram showing a memory card according to an embodiment of the invention.

FIG. 2 is a diagram showing four kinds of threshold voltage distributions of a nonvolatile memory cell.

FIG. 3 is a diagram illustrating the relation between write data to a nonvolatile memory cell and retained information.

FIG. 4 is a diagram illustrating an operation of writing data to a flash memory of the memory card.

FIG. 5 is a diagram showing an operation of reading data from a flash memory of the memory card.

FIG. 6 is a diagram illustrating the structure of a storage area such as a management information area in a memory array of the flash memory.

FIG. 7 is a diagram illustrating the details of an alternative registration table.

FIG. 8 is a diagram illustrating the details of management information.

FIG. 9 is a flowchart showing an operation of reading data from a memory card in response to a read instruction from a host.

FIG. 10 is a flowchart showing the first half of an operation of writing data to a memory card in response to a write instruction from the host.

FIG. 11 is a flowchart showing the latter half of the operation of writing data to the memory card in response to the write instruction from the host.

FIG. 12 is a timing chart illustrating read operation timings of a flash memory.

FIG. 13 is a timing chart illustrating write operation timings of the flash memory.

FIG. 14 is a flowchart showing the details of an alternative retrieving process.

FIG. 15 is a flowchart showing the details of an alternate process.

FIG. 16 is a timing chart illustrating timings of writing data to a memory card by the host.

### DETAILED DESCRIPTION OF THE PREFERRED EMBODIMENTS

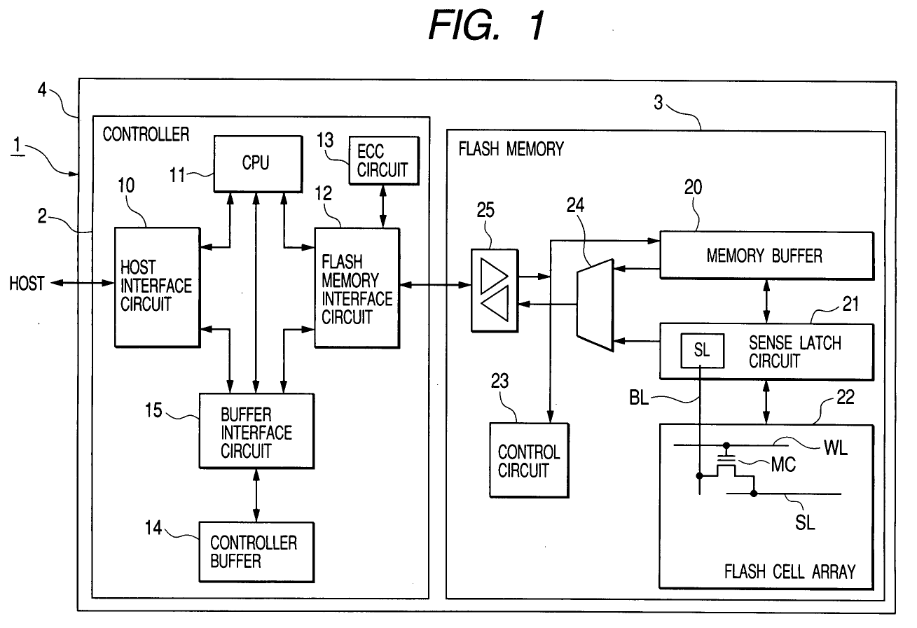

FIG. 1 shows a memory card according to an embodiment of the invention. A memory card 1 is constructed in such a manner that a controller 2 and a nonvolatile memory such as a flash memory 3 are mounted on a card board 4 and the surface of the card board is sealed with a not-shown casing or resin. The controller 2 has a host interface circuit 10, a CPU 11, a flash memory interface circuit 12, an ECC circuit 13, a controller buffer 14, and a buffer interface circuit 15.

The host interface circuit 10 accepts a command issued by a not-shown host, notifies the CPU 11 of the command, and controls data transfer between the host and controller buffer 14 in accordance with a setting of the CPU 11. A protocol of reading/writing data between the host interface circuit 10 and the host may be a predetermined protocol such as ATA (AT Attachment) , SCSI (Small Computer System Interface), or an interface dedicated to a memory card.

The CPU 11 analyzes the command issued by the not-shown host, executes calculation of the address in the flash memory 3 to be accessed, makes a setting of data transfer with the host in the host interface circuit 10 and a setting of data transfer with the flash memory in the flash memory interface circuit 12, and the like.

The flash memory interface circuit 12 controls a data transfer between the controller buffer 14 and the flash memory 3 in accordance with an instruction of the CPU 11.

At the time of writing data to the flash memory 3, the ECC circuit 13 generates an error correcting code and adds the code to write data. At the time of reading data from the flash memory 3, the ECC circuit 13 detects an error by using the error correcting code. In the case where an error occurs in the read operation, an error correction is made.

The controller buffer 14 functions as a data buffer between the flash memory 3 and the host and temporarily holds write data from the host to the flash memory 3 or temporarily holds output data from the flash memory 3 to the host. The controller buffer 14 is constructed by, for example, an SRAM (Static Random Access Memory) . The buffer interface circuit 15 controls reading/writing of the controller buffer 14. The controller buffer 14 may be constructed on a chip different from the controller 2. Alternately, the controller 2 and the flash memory 3 may be formed in one chip.

The flash memory 3 includes a memory buffer 20, a sense latch circuit 21, a memory array (flash cell array) 22, a control circuit 23, a selector 24, and an input/output circuit 25. The memory buffer 20 is constructed by, for example, an SRAM. Although not shown, when one memory bank is formed by the memory buffer 20, sense latch circuit 21, and memory array 22, a plurality of memory banks may be provided.

A number of nonvolatile memory cells MC, one of which is representatively shown, are disposed in a matrix in the memory array 22. Although not limited, one memory cell is constructed by a known floating-gate transistor. For example, a nonvolatile memory cell is constructed by a source and a drain formed in a well region, a floating gate formed via a tunnel oxide film in a channel region between the source and the drain, and a control gate stacked on the floating gate via an interlayer insulating film. The control gate is connected to a representatively-shown word line WL, the drain is connected to a representatively-shown bit line BL, and the source is connected to a representatively-shown source line SL. To one end of the bit line BL, a sense latch SL constructed by a static latch circuit is connected. The sense latch circuit 21 includes an array of the sense latches SL arranged every bit line.

By using a change in threshold voltage of a memory cell according to an amount of charge accumulated in the floating gate, information is stored in the nonvolatile memory cell MC. In the nonvolatile memory cell MC, for example, when electrons are injected into the floating gate, the threshold voltage increases. When electrons are withdrawn from the floating gate, the threshold voltage decreases. The threshold voltage is set by a control in a state where a voltage is applied to the word line, source line, bit line, and board. Since the control method is known, it will not be specifically described here.

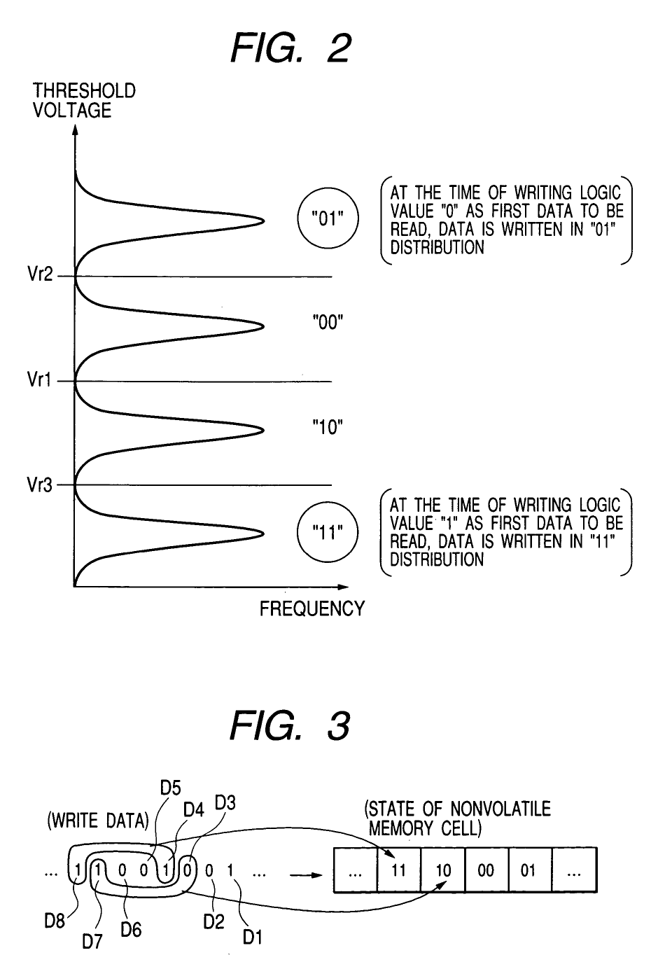

The nonvolatile memory cell MC can be set to, although not limited, as shown in FIG. 2, a threshold included in one of the four or more kinds of threshold voltage distributions. In this example, data of two bits can be stored in a single nonvolatile memory cell, and four kinds of memory threshold voltage distributions corresponding to data “01”, “00”, “10”, and “11” are determined. Specifically, an information storing state of a memory cell is selected from an erase state (“11”) as a fourth threshold voltage (Vth4) state, a first write state (“10”) as a first threshold voltage (Vth1) state, a second write state (“00”) as a second threshold voltage (Vth2) state, and a third write state (“01”) as a third threshold voltage (Vth3) state. Although not particularly limited, the threshold voltages have the relation of Vth4<Vth1<Vth2<Vth3. Each of the total four kinds of information storing states is determined by 2-bit data.

To obtain the memory threshold distribution, although not limited, first, a nonvolatile memory cell is set in the erase state. In the case of obtaining the write state, a high-voltage pulse or the like necessary to increase the threshold voltage is sequentially applied to word lines or the like. Each time or every a few times the high-voltage pulse is applied, a read operation using a verify voltage in the first write state is performed to verify whether the first write state is set or not. In the case where the second write state is required, similar verification is performed by using the verify voltage of the second write state. In the case where the third write state is required, similar verification is performed by using a verify voltage of the third write state.

By application of the high-voltage pulse, for example, 0V is applied to a bit line of a memory cell to which data is to be written and a write suppress voltage 1V is applied to a bit line which is not selected for writing. Either the write select voltage of 0V or the write suppress voltage of1V is applied to a bit line is determined by a logic value of write control information latched by the sense latch SL. For example, it is controlled so that when the logic value of latch data of the sense latch SL is “1”, writing is not selected, and when the logic value is “0”, writing is selected. Which one of “1” or “0” is set in the sense latch SL in the write operation is determined by the control circuit 23 in accordance with write data on the memory buffer 20 on the basis of the write threshold voltage state. For example, as shown in FIG. 3, when attention is paid to write data D8 to D1 of one byte (8 bits)=11001001, the threshold voltages of nonvolatile memory cells corresponding to units each consisting of two bits, specifically, two bits “11” of D8 and D4, two bits “10” of D7 and D3, two bits “00” of D6 and D2, and two bits “01” of D5 and D1. “1” indicating that writing is not selected is set in the sense latch SL according to the nonvolatile memory cell in which D8 and D4=11. “0” indicating that writing is selected is set in the sense latch SL corresponding to the nonvolatile memory cell in which D7 and D3=10 until the first write state is obtained. “0” indicating that writing is selected for the sense latch SL corresponding to the nonvolatile memory cell in which D6 and D2=00 until the second write state is obtained. “0” indicating that writing is selected is set in the sense latch SL corresponding to the nonvolatile memory cell in which D5 and D1=01 until the third write state is obtained. The control is performed by the control circuit 23 and the sense latch circuit 21 on the basis of write data in the memory buffer 20. The control circuit 23 generates high voltages necessary for the writing process and the erasing process and generates an access address.

Information stored in the nonvolatile memory cell in which the threshold voltage is set can be read by the following two operations. In a second reading operation, one of the four kinds of threshold voltage distributions in FIG. 2, to which the threshold voltage belongs is determined and information read from the nonvolatile memory cell is output as 2-bit information. In a first reading operation, the present state is determined from the third write state (“01”) as the highest threshold voltage distribution and the erase state (“11”) as the lowest threshold voltage distribution, and information read from the nonvolatile memory cell is output as 1-bit information. In the case of determining the four kinds of threshold voltage distributions, according to the example of FIG. 2, first, the read word line voltage is set as Vr1 and 0 and 1 of the upper one bit in two bits is determined. When the upper one bit is 0, the read word line voltage is set as Vr2 and 0 or 1 is determined as the lower one bit in two bits. When the upper one bit is 1, the read word line voltage is set as Vr3 and 0 or 1 is determined as the lower one bit in two bits. In such a manner, the upper one bit in 2-bit storage information is determined and, after that, the upper one bit is saved from the sense latch SL to a corresponding storage element in the memory buffer 20. The result of determination of the next lower bit is obtained in the sense latch SL. The result of determination of the lower one bit is also similarly transferred from the sense latch SL to a corresponding storage element in the memory buffer 20. The information read from the memory buffer 20 is output to the controller 2.

In the first reading operation of outputting information read from a nonvolatile memory cell as 1-bit information, according to the example of FIG. 2, the read word line voltage is set as, for example, Vr3 and a result of determination of the stored information 0 or 1 is latched by the sense latch SL. Since the determination value latched in the sense latch SL is storage information to be read itself, it is unnecessary to save the information into the memory buffer 20 but can be supplied from the input/output circuit 25 to the controller 2 via the selector 24.

The control of erasing, writing, and reading data from/to the flash memory array 22 is performed by the control circuit 23 on the basis of a command supplied from the controller 2. The command includes a command code for instructing an operation, an access address for instructing an object to be accessed, and write data accompanying the instruction of writing operation.

Although not limited, the storing operation instructed by the command includes: an operation of transferring write data from the outside into the memory buffer 20; an operation of writing write data in the memory buffer 20 into a nonvolatile memory cell in the memory array 22; a second outputting operation of reading data from the nonvolatile memory cell, storing it in the memory buffer 20, and outputting the data held in the memory buffer 20 to the outside for the second reading operation; and a first outputting operation of reading data from the nonvolatile memory cell and outputting the data to the outside for the first reading operation. The address to be accessed in each of the operations is instructed by a command. In the case where the access unit is large, the head address of an access unit is given and it is sufficient to automatically generate the subsequent addresses by an address counter in the control circuit 23. The other detailed configuration of the flash memory 3 is disclosed in International application of PCT/JP02/03417 filed by the applicant of the present invention.

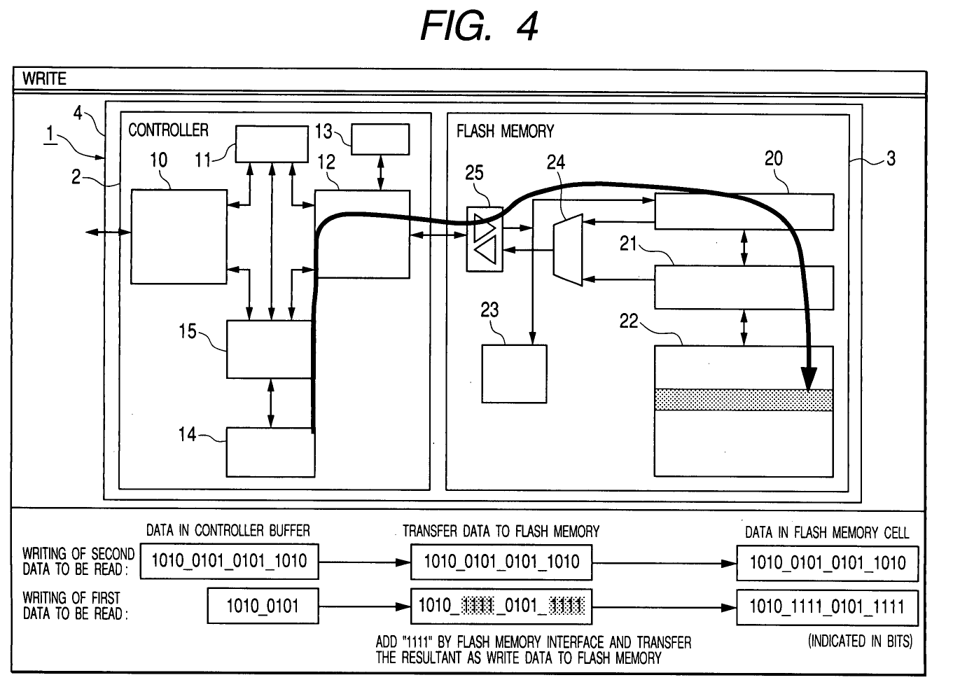

FIG. 4 shows an example of the operation of writing data into the flash memory 3 in the memory card 1. In FIG. 4, second data to be read is data which is written by the host into the memory card 1, and first data to be read is data used by the controller 2 to manage data to be written into the memory card by the host. For example, write data “1010_{—}0101_{—}0101_{—}1010” is transferred from the host to the controller buffer 14. The transferred write data is the second data to be read in this example. When the write data is the second data to be read, the controller 2 supplies the write data “1010_{—}0101_{—}0101_{—}1010” as it is to the memory buffer 20. After that, the controller 2 given an instruction of rewriting the information stored in the memory array 22 with the write data of the memory buffer 20. By the operation, in the nonvolatile memory cell to be rewritten, a threshold voltage included in one of the four kinds of threshold voltage distributions is set in accordance with the write data on a two-bit unit basis. A case where the controller 2 writes “1010_{—}0101” as first data to be read into the flash memory 3 to make the host manage data to be written into the memory card 1 will now be described. The first data “1010_{—}0101” to be read is data written by the CPU 11 into the controller buffer 14. When the write data is the first data to be read, the controller 2 divides the write data every four bits, adds 4-bit mask data “1111” to the low-order side of the write data, and supplies the resultant as write data “1010_{—}1111_{—}0101_{—}1111” to the memory buffer 20. The controller 2 gives an instruction of rewriting data stored in the memory array 22 with the write data in the memory buffer 20 to the flash memory 3. In a nonvolatile memory cell to be rewritten, therefore, a threshold voltage included in one of the four kinds of threshold voltage distributions is set on a 2-bit unit basis in accordance with the write data as described above. By adding the 4-bit mask data “1111” to the low-order side of every 4-bit write data, a threshold voltage included in the distribution of either the third write state (“01”) as the highest threshold voltage distribution in the four kinds of threshold voltage distributions or the erase state (“11”) as the lowest threshold voltage distribution is set on the 2-bit unit basis.

As described above, at the time of writing the first data to be read, out of the four kinds of threshold voltage distributions, “11” (the threshold voltage distribution of the highest-order level as an erase state) and “01” (the threshold voltage distribution of the lowest-order level as the write state) are used. Consequently, even when the threshold voltage of a nonvolatile memory cell changes due to disturbance or retention, if the threshold voltage moves only to an adjacent distribution, the first data to be read is not garbled. Thus, reliability of information storage is improved.

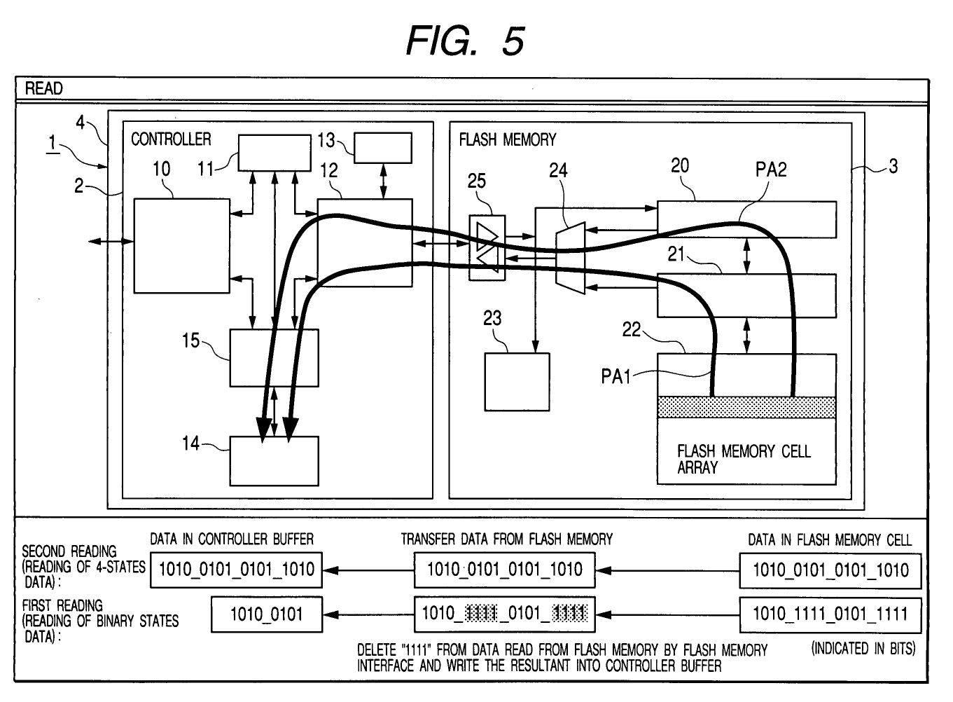

FIG. 5 shows an example of an operation of reading data from the flash memory 3 in the memory card 1. When the host reads data from the memory card 1, the controller 2 reads management data for the data read by the host from the flash memory 3 by the first reading operation. After that, the controller 2 reads out data to be read by the host from the flash memory 3 by the second reading operation. In the first reading operation, the controller 2 instructs the control circuit 23 by a command to perform the first reading operation. In this case, for example, when information stored in a memory cell to be read is “1010_{—}1111_{—}0101_{—}1111”, by a single threshold voltage determining operation in the case of the first reading operation, the read data “1010_{—}0101” can be obtained in the sense latch SL. The read data “1010_{—}0101” obtained at the sense latch SL is transferred to the controller buffer 14 via a bypass of the memory buffer 20 selected by the selector 24 and read by the CPU 11. In the second reading operation, the controller 2 instructs the control circuit 23 to perform the second reading operation by a command. In this case, for example, when the information stored in the memory cell to be read is “1010_{—}0101_{—}0101_{—}1010”, the memory buffer 20 obtains results of the threshold voltage determining operations of twice in the case of the second reading operation, the read data stored in the memory buffer 20 is transferred to the controller buffer 14, and the stored information “1010_{—}0101_{—}0101_{—}1010” is output as it is to the host. In FIG. 5, PA1 denotes a reading path of the first reading operation, and PA2 denotes a reading path of the second reading operation.

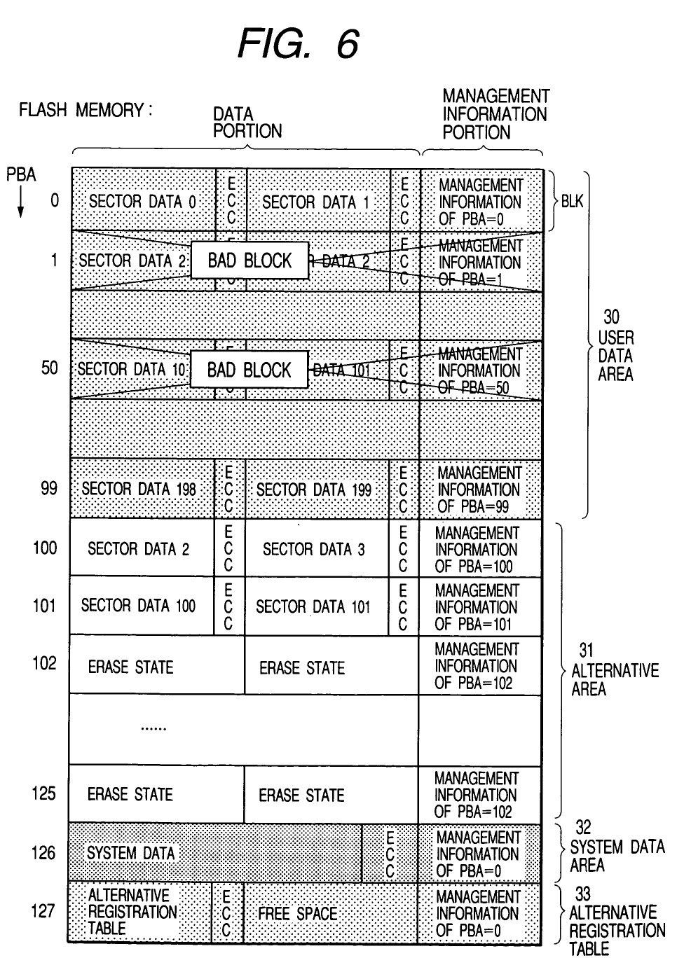

FIG. 6 illustrates the configuration of the data region in the memory array 22. This example relates to the case of realizing a file structure. Although not particularly limited, sector data consists of 512 bytes. An ECC code is added to each sector data. One piece of management information is provided for two pieces of sector data. One block BLK is constructed by two sector data regions (data portion) and a management region for storing management information for the data portion. Although not limited, data is erased or written on the block unit basis. Specifically, each of a source line and a word line is commonly used for a plurality of nonvolatile memory cells included in one block. In this example, the erasing unit and the writing unit are the same. There is also a case that the erasing unit is larger than the writing unit.

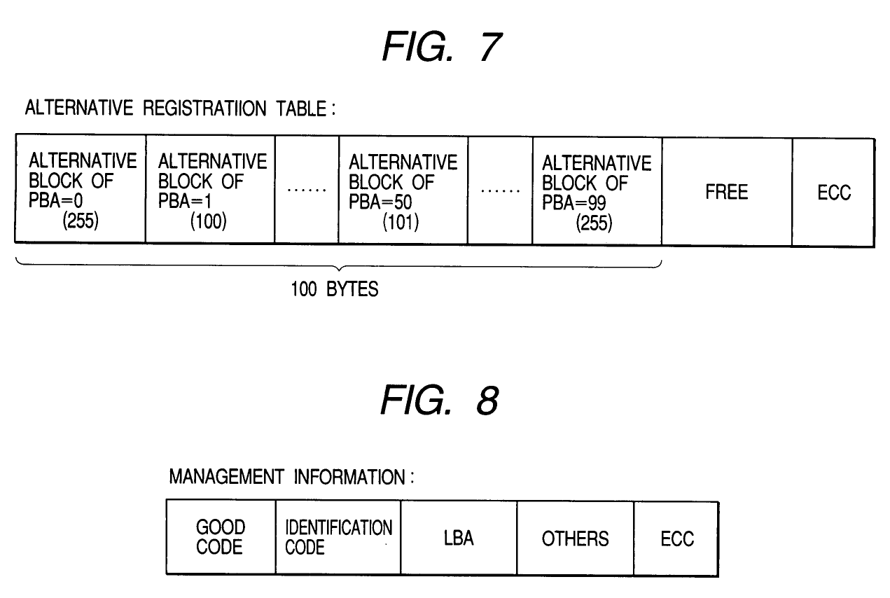

PBA is an abbreviation of Physical Block Address. A flash memory in this example consists of 128 blocks. PBAs 0 to 99 form a user data area 30. The user data area 30 is an area in which data written by the host is written. PBAs 100 to 125 form an alternative area 31. The alternative area 31 is used to replace a block which becomes bad. In a block (system data area) 32 having PBA of 126, system data is stored. The system data is information such as the ID of a memory card or the ID number peculiar to a memory card. A block having PBA of 127 is an area (alternative registration table) 33 in which information of a block replaced with the replacement area is stored in a table. Since the user data area consists of 100 blocks (PBA=0 to 99), the alternative registration table is constructed by total 100 bytes in which an alternative designation area is assigned to each block on a byte unit basis. For example, as shown in FIG. 7, the alternative designation areas are sequentially assigned from the head like PBA1, PBA2, . . . In the case where an alternative is unnecessary, the code number 255 is stored. In the example of FIG. 7, PBA=1 and PBA=50 are bad, so that code number 100 is stored in the area PBA=1 in the alternative registration table and code number 101 is stored in the area of PBA=50. It denotes that PBA=1 is replaced by PBA=100, and PBA=50 is replaced by PBA=101.

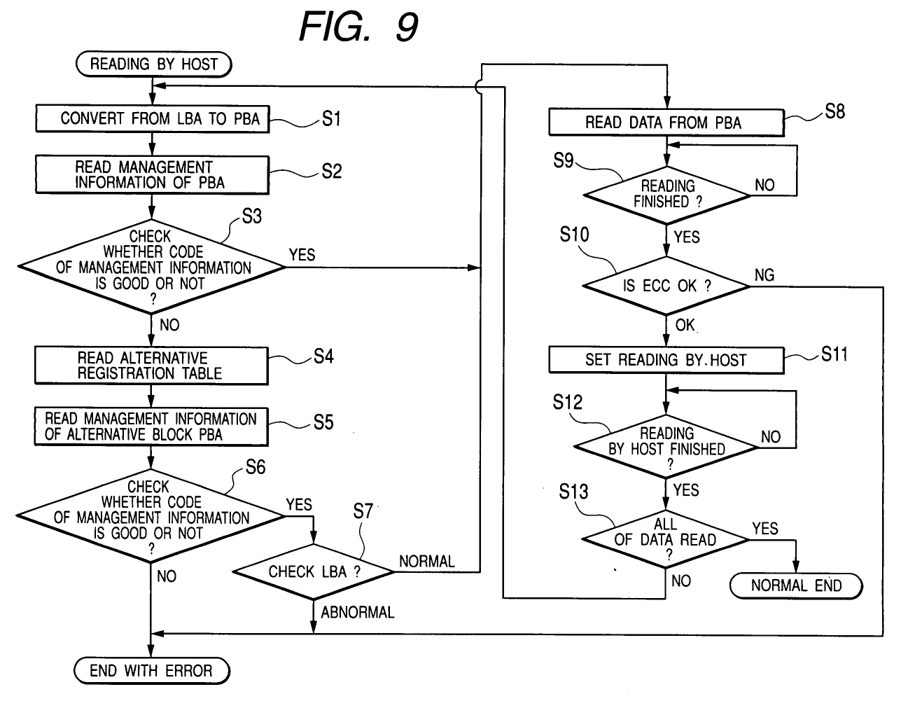

The management information is constructed by, as shown in FIG. 8, a good code (fixed value) indicative of a good block (block which can normally perform a storing operation), an identification code for identifying the block, logical block address (LBA) of the host, other information and ECC. In the case of data other than a good code, it expresses that the block is bad and the other data is invalid. The identification code indicates that the block is any of a user data block, a spare block, a free block, a system block and an alternative registration table block.

In the memory array of FIG. 6, a first area to be read is the management information area and the system data area. Information stored in the first area to be read is first information. The other area is a second area to be read. Information stored in the second area to be read is second information. By using the management information area as the first area to be read, the speed of a first access is increased. By using the system data area as the first area to be read, from a viewpoint of a property such that data which is very important for operation of a memory card is stored, the reliability of storage of such important data is improved.

FIG. 9 shows a flowchart of reading operation of the memory card 1 performed in response to a reading instruction from the host. When an operation of reading data is instructed by the host (reading by the host), the controller 2 converts a logic block address from the host into a physical block address of the flash memory 3 (S1) and reads out management information of the physical block address from the flash memory 3 (S2). This reading corresponds to the first reading operation. The controller 2 checks whether the code of management information is good or not (S3). If NO, the controller 2 reads an alternative registration table (S4), reads management information of an alternative block PBA indicated by the table (S5) , and checks whether the code of management information is good or not (S6). Reading of the management information is performed by the first reading operation. If a good code cannot be obtained by the reading operation, the routine is finished. If the code of management information is good in S6, the controller 2 checks the LBA of the management information (S7) and, if the LBA is normal, reads data from a PBA as an alternative (S8 and S9). The read data is output by the second reading operation. The controller 2 checks if an ECC is OK on the read data (S10). If there is an error which cannot be corrected, the routine is finished. If there is no error which cannot be corrected, the controller 2 notifies the host of a reading ready state of the controller buffer 14 (S11), waits for completion of reading by the host (S12), after completion of the reading, and determines whether reading of all of necessary data is finished by the host or not (S13). If YES, the routine is normally finished. If NO, the controller 2 returns to step S1 and re-starts an operation of reading the next data from the flash memory 3.

Since the management information is always read in the reading by the host, the time for reading the management information can be shortened by the first reading operation, so that the reading of the host is accordingly increased.

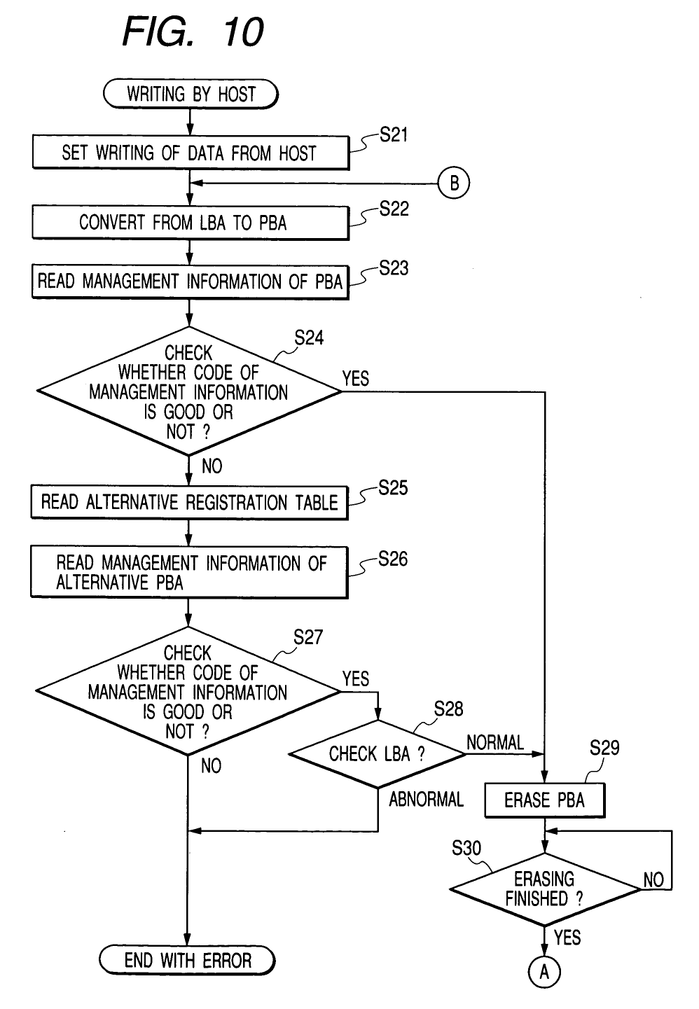

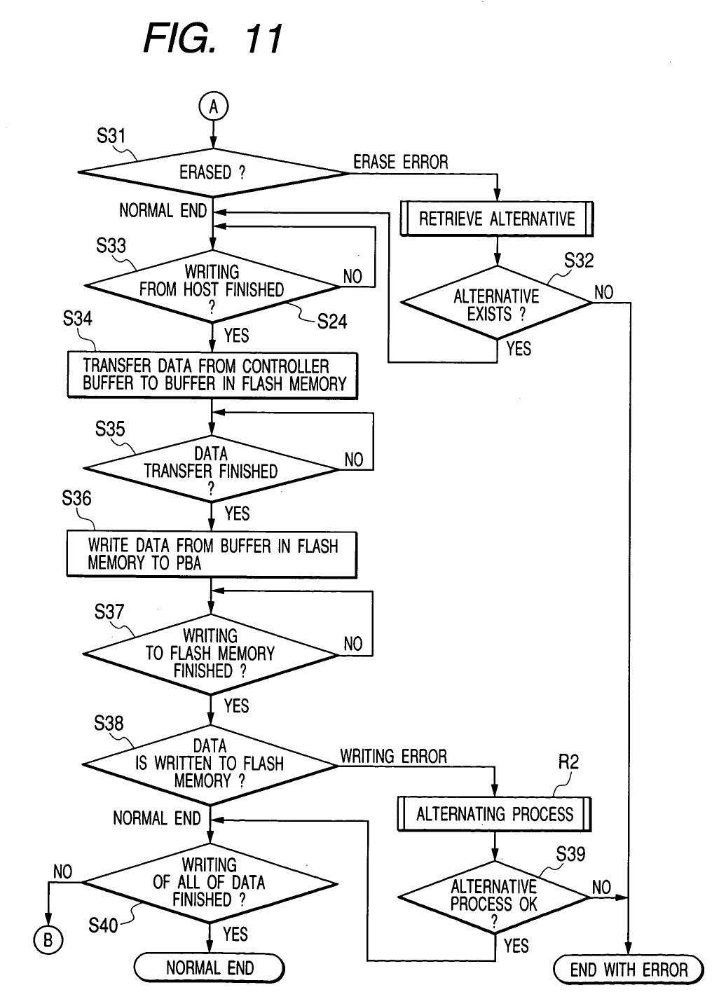

FIGS. 10 and 11 show a flowchart of a writing operation of the memory card 1 performed in response to a writing instruction from the host. When the data writing operation is instructed by the host, the controller 2 stores write data supplied from the host into the controller buffer 14 (S21). The controller 2 converts a logical block address from the host into a physical block address of the flash memory 3 (S22) and reads out management information of the physical block address from the flash memory 3 (S23). This reading operation corresponds to the first reading operation. The controller 2 checks whether the code of management information is good or not (S24). If NO, the controller 2 reads an alternative registration table (S25), reads management information of an alternative PBA indicated by the table (S26), and checks whether the code of the management information is good or not (S27). The management information is read by the first reading operation. When a good code cannot be obtained by the first reading operation, the routine is finished with an error. If a good code is obtained in step S27, the LBA of the management information is checked (S28) . If the LBA is normal, the process of erasing the PBA as an alternative is carried out (S29 and S30). Whether the PBA is erased or not is determined (S31) . When an erase error occurs, an alternative retrieving process R1 is performed and the presence or absence of the alternative is determined (S21). If there is no alternative, the routine is finished. If there is an alternative and it is determined in S31 that the PBA is erased normally, the controller 2 waits for completion of the supply of write data from the host (S33) , and write data is transferred from the controller buffer 14 to the memory buffer 20 in the flash memory 3 (S34 and S35). After completion of the data transfer, data is written from the memory buffer 20 in the flash memory 3 into the PBA (S36) . Completion of the writing is determined (S37) and a result of writing is determined (S38). If there is a write error, an alternating process (R2) is performed and whether an alternative exists or not is determined (S39) If there is no alternative, the routine is finished. If there is an alternative, whether writing of all of the data required by the host has been finished or not is determined (S40). When the writing of all of the data is finished, the routine is finished normally. If the writing of all of the data is not finished yet, the controller 2 returns to step S22 and continues writing of the rest.

Since management information is always read in the writing by the host, the management information read time can be shortened by the first reading operation and it enables the writing by the host to be performed faster.

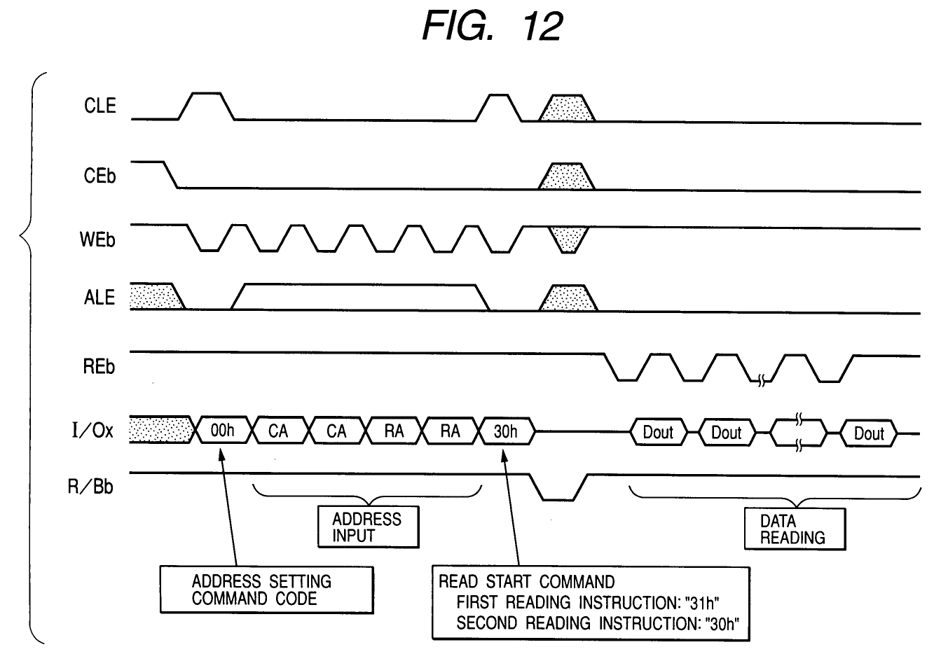

FIG. 12 illustrates timings of operation of reading the flash memory 3. Shown are an external input/output terminal I/Ox commonly used for inputting an address, inputting/outputting data, and inputting a command, a command latch enable signal CLE, an address latch enable signal ALE, a chip enable signal CEb, a read enable signal REb, a write enable signal WEb, and a ready busy signal R/Bb. The flash memory 3 interfaces with the controller 2 via the input/output circuit 25. The chip enable signal CEb shows a chip selection state to the flash memory 2. The read enable signal REb instructs an operation of reading data from the external input/output terminal I/Ox, and the write enable signal WEb instructs an operation of writing data from the external input/output terminal I/Ox. The command latch enable signal CLE indicates that a command is supplied from the outside to the external input/output terminal I/Ox. The address latch enable signal ALE indicates supply of an address signal from the outside to the external input/output terminal I/Ox. The ready/busy signal R/Bb indicates by its low level that erase, write, or read operation is being performed (busy state) on the flash memory array 22. 00h indicates an address setting command code, CA denotes a column address, RA denotes a row address, and 30h expresses a read start command code by the second reading operation. When the read start command code 30h is supplied, an operation of reading data Dout from the memory array is started. The read start command code by the first reading operation is 31h.

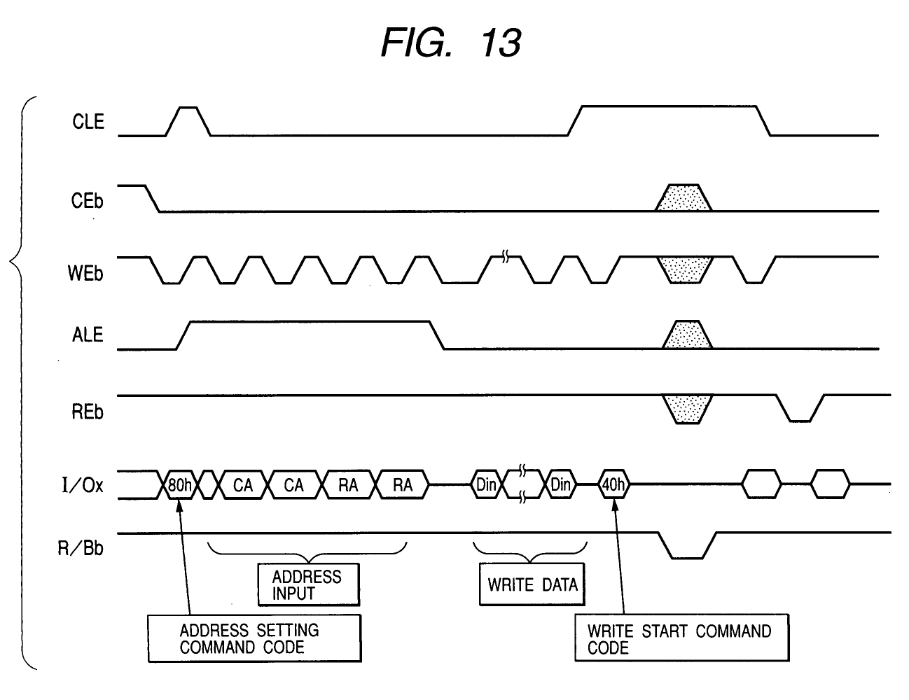

FIG. 13 illustrates timings of operation of writing data to the flash memory 3. Shown are an address setting command code 80h, a column address CA, a row address RA, write data Din, and a write start command code 40h. When the write start command code 40h is supplied, the data Din is written into the memory array 22. In the flash memory 3, a flash memory writing operation in the first area to be read and that in the second area to be read are the same. In writing to the first area to be read, on the controller 2 side, addition of the mask data to write data is completed.

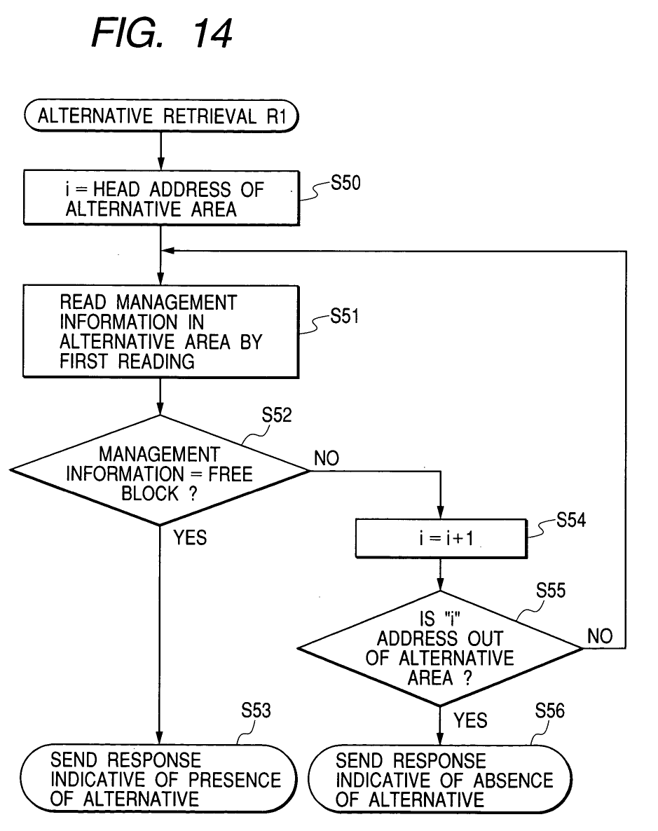

FIG. 14 shows an example of the alternative retrieving process R1. First, the head address of an alternative area is substituted into a retrieval parameter “i” (S50), and management information in a corresponding alternative area is read by the first reading operation by using the substitute value of the parameter “i” as an address (S51). Whether the block is a free block or not is determined on the bass of the identification code from the read management information (S52). If the block is a free block, a response indicative of the presence of an alternative is sent (S53) If there is no free block, the parameter “i” is incremented by +1 (S54) . Whether the address indicated by the value “i” lies out of the alternative area range or not is determined (S55). If YES, a response indicative of the absence of an alternative is sent (S56). If NO, the program returns to step S51 and the retrieval is continued.

Management information in the alternative retrieving process is read by the first reading operation. The read data is output via the path PA1 shown in FIG. 5. Therefore, in the reading of the management information, the memory buffer 20 in the flash memory 3 is not used, and write data stored in the memory buffer 20 prior to the alternative retrieving process remains without being destroyed. Therefore, it is unnecessary to save the write data in the memory buffer into the controller buffer 14 in the controller 2 to retrieve an alternative.

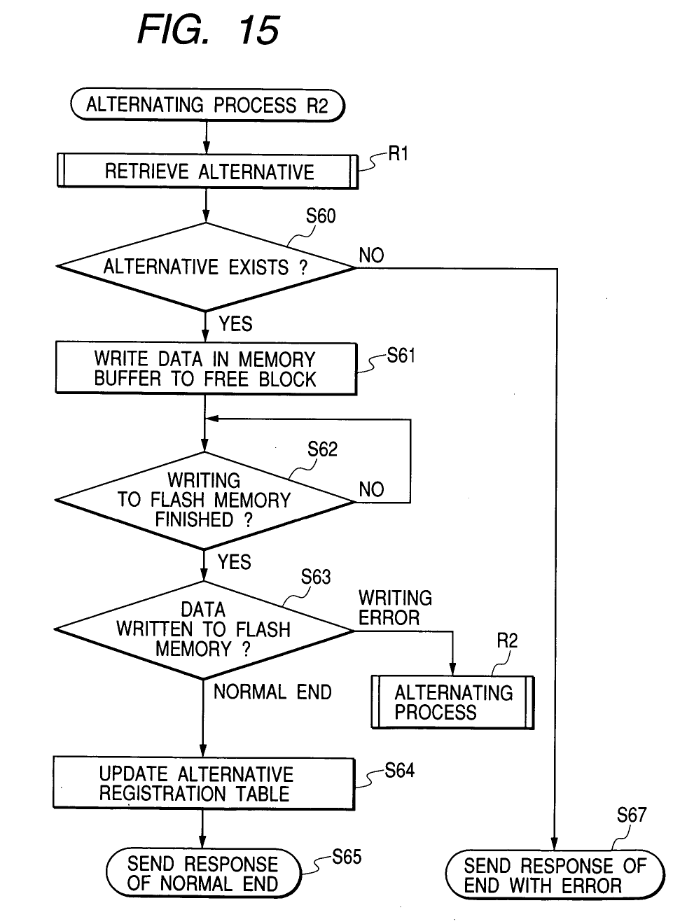

FIG. 15 illustrates an example of the alternating process R2. First, after the alternative retrieving process R1, whether there is an alternative or not is determined (S60). When an alternative exists, the response indicative of the presence of an alternative in FIG. 14 (S53) is obtained. When an alternative does not exist, the response indicative of the absence of an alternative in FIG. 14 (S56) is obtained. If an alternative does not exists, an error response is returned (S67). If there is an alternative, a process of writing data in the memory buffer into a free block as the alternative is performed (S61 and S62). The free block is erased before the writing process. The result of the writing process is checked (S63). If the writing process is normally finished, the alternative registration table is updated (S64) and a response indicative of normal end (normal response) is returned. If there is a write error, the alternating process R2 is performed to deal with the write error.

As obvious from the alternating process R2, after an alternative is retrieved by the alternative retrieving process R1, data stored in the memory buffer 20 in the flash memory 3 can be written into the alternative (S61). In short, in the alternating process R2, it is unnecessary to re-transfer the write data from the controller buffer 14 in the controller 2.

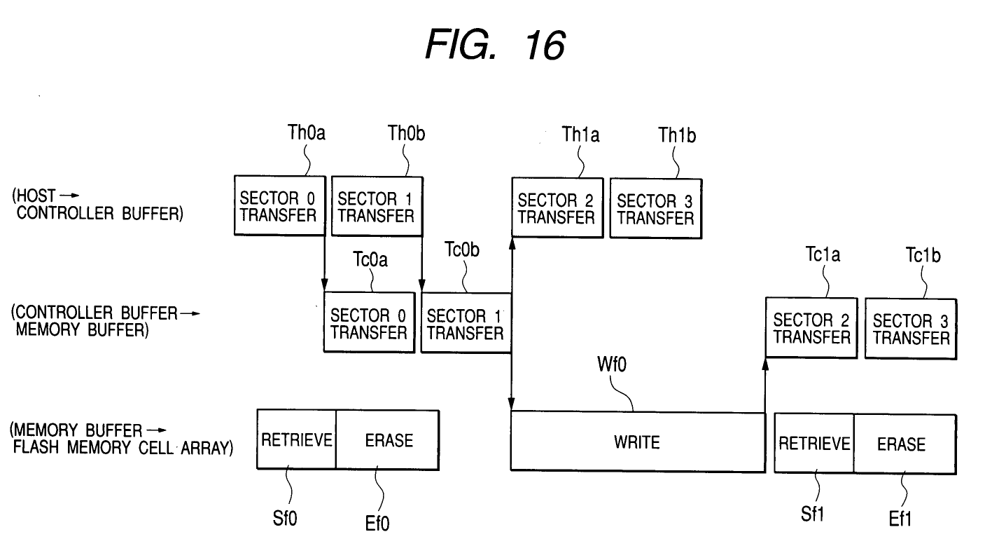

FIG. 16 shows timings of writing data into the memory card 1 by the host. The host instructs the controller 2 to write data and transfers write data on a sector unit basis. In FIG. 16, the host transfers write data of sectors 0 and 1 to the controller 2 (Th0a and Th0b) and stores the write data into the controller buffer 14 in the controller 2. In response to a write instruction from the host, the controller 2 makes the flash memory 3 execute a process (Sf0) of retrieving blocks corresponding to the sectors 0 and 1 and an erasing process (Ef0) on the retrieved blocks. The write data in the sectors 0 and 1 stored in the controller buffer 14 is transferred from the controller 2 to the flash memory 3 (Tc0a and Tc0b) and stored into the memory buffer 20 in the flash memory 3. After that, the flash memory 3 performs a process (Wf0) of writing the data in the sectors 0 and 1 stored in the memory buffer 20 into the blocks subjected to the retrieving process and the erasing process. In parallel with the writing process (Wf0), the host transfers the write data in the next sectors 2 and 3 to the controller 2 (Th1a and Th1b) since the controller buffer 14 is not used for the writing but is free during the writing process of the flash memory 3. After completion of the writing process (Wf0) in the flash memory 3, the write data in the sectors 2 and 3 stored in the controller buffer 14 is transferred from the controller 2 to the flash memory 3 (Tc1a and Tc1b) and stored into the memory buffer 20 in the flash memory 3. In parallel with the transfer, the controller 2 makes the flash memory 3 execute, in advance, the process (Sf1) of retrieving blocks corresponding to the sectors 2 and 3 and the process (Ef1) of erasing data in the retrieved blocks. After that, the flash memory 3 performs the process of writing the data in the sectors 2 and 3 stored in the memory buffer 20 into the blocks subjected to the retrieving process and the erasing process.

As obvious from the writing timings of the host shown in FIG. 16, during the process of writing the write data into a nonvolatile memory cell in the flash memory, the next write data can be transferred from the host to the controller buffer 14 in the controller 2. As described above, even if a write error occurs in the flash memory 3, the write data in the memory buffer 20 is not destroyed by the alternative retrieving process. Consequently, the writing process and the process of transferring the next write data can be performed in parallel without increasing the capacity of the controller buffer 14.

By the memory card, the following effects are obtained.

[1] The flash memory 3 can set a threshold voltage included in one of four kinds of threshold voltage distributions in the nonvolatile memory cell MC, and the first reading operation of outputting information read from the nonvolatile memory cell MC in which the threshold voltage is set as 1-bit information, and the second reading operation of outputting information read from the nonvolatile memory cell MC in which the threshold voltage is set as 2-bit information can be performed. At the time of reading first information such as the management information or the information stored in the system data area from the flash memory 3, the controller 2 performs the first reading operation. At the time of reading second information such as sector data or an alternative registration table from the nonvolatile memory, the controller 2 performs the second reading operation. The number of operations of checking the threshold voltage of the nonvolatile memory cell MC in the first reading operation of outputting information read from the nonvolatile memory cell MC in which a threshold voltage included in one of the four or more kinds of threshold voltage distributions is set as 1-bit information is smaller than that in the second reading operation of outputting information read from the nonvolatile memory cell MC as 2-bit information. Therefore, the reading operation can be performed faster by that amount. By using sector data in the data portion or the like as the second information as a second object to be read and using management information or the like as first information as a first object to be read, time required to read the management information at the time of reading/writing from the host can be shortened. Thus, the speed of operation of reading/writing the memory card 1 by the host can be increased.

[2] In the flash memory 3, at the time of storing the first information into the nonvolatile memory cell MC, either the voltage in the upper-limit threshold voltage distribution (“01” area) or the voltage in the lower-limit threshold voltage distribution (“11” area) is used as the threshold voltage of the nonvolatile memory cell MC. Therefore, a threshold voltage distribution area which is not directly used for storing information is interposed between the threshold voltage distributions used for storing information. Thus, resistance to a retention error caused by a change with time or the like can be improved in the system data area as the storage area of the first information. The reliability of information storage in the system data area or the like can be improved.

[3] The flash memory 3 has the memory buffer 20 used for the process of writing data to the nonvolatile memory cell MC and used for the second reading operation. The first information such as management information read as 1-bit information from each of the plurality of nonvolatile memory cells by the first reading operation is output to the controller 2 while bypassing the memory buffer 20. At the time of reading information as 2-bit information, the memory buffer 20 in the flash memory 3 is not used. Therefore, when a write error occurs at the time of writing data into the flash memory 3, while holding write data in the memory buffer 20 in the flash memory 3, an alternative can be retrieved by an operation of reading 1-bit information. Therefore, it is unnecessary to perform the process of saving write data from the memory buffer 20 into the buffer 14 in the controller 2, the process of retrieving an alternative area can be performed promptly when a write error occurs and, moreover, the capacity of the buffer 14 in the controller 2 can be suppressed.

[4] By the above, increase in speed of data transfer of the memory card 1 on which the flash memory 3 is mounted and improved reliability can be realized.

Although the invention achieved by the inventors herein have been concretely described on the basis of the embodiments, the invention is not limited to the embodiments. Obviously, the invention can be variously modified without departing from the gist.

For example, an SRAM is used as the memory buffer 20 used to read 4 states data, the invention is not limited to the SRAM. The memory buffer may be constructed by a latch circuit in which static latches are arranged in parallel in a plurality of stages.

Although the nonvolatile memory in the example can store 4 states data, a memory card on which the nonvolatile memory for storing multi-value data of four or more states is stored may be used. The number of the flash memory mounted on the memory card is not limited to one but may be plural.

The form of storing a multi-value flash memory is not limited to the case where the threshold voltage is varied sequentially in accordance with the values of stored information. A memory cell structure of using a charge trap film (nitride silicon film) for storing multi-value data by locally changing a location for holding a charge in a memory cell may be also employed. Further, as the nonvolatile memory cell, another storing form such as a high-dielectric-constant memory cell can be employed. The relation between write data to the nonvolatile memory cell and retained information is not limited to FIG. 3 but can be properly changed.

The invention is not limited to a structure in which both an address and data are multiplexed and input to an I/O terminal but a structure including an address terminal for inputting an address may be also employed. A command for designating either an access to a buffer memory or an access to a flash memory array in accordance with an address input from the address terminal may be provided.

Concrete kinds of the first and second information are not limited to the above description but can be properly changed according to the kind of a nonvolatile memory apparatus. In the case of applying the invention to a microcomputer for an IC card, user ID information of an IC card may be processed as first information.

The invention can be widely applied to a flash memory card, a microcomputer, a system LSI, and the like. The invention can be used for a storage medium of a PDA (Personal Digital Assistant) or a portable telephone.

Effects obtained by representative ones of the inventions disclosed in the specification will be briefly described as follows.

In the nonvolatile memory apparatus in which the nonvolatile memory and the controller are mounted, the performance of read/write speeds can be improved.

In the nonvolatile memory apparatus in which the nonvolatile memory and the controller are mounted, resistance to a retention error caused by a change with time or the like can be improved in a required storage area.

In the nonvolatile memory apparatus in which the nonvolatile memory and the controller are mounted, at the time of performing an operation of reading a nonvolatile memory cell in order to retrieve an alternative area in the case where a write error occurs during writing of data to the nonvolatile memory, it is unnecessary to save write data held in the data buffer in the nonvolatile memory.

What is claimed is:

1. A nonvolatile memory apparatus comprising a nonvolatile memory and a controller,
wherein said nonvolatile memory has a plurality of nonvolatile memory cells each capable of storing information of n bits (n: integer of 2 or larger), and can perform a first reading operation of outputting information read from said nonvolatile memory cell as information of m bits (m: integer smaller than n) and a second reading operation of outputting information read from said nonvolatile memory cell as information of n bits, and
wherein said controller performs the first reading operation to read first information from said nonvolatile memory and performs the second reading operation to read second information from said nonvolatile memory.

2. The nonvolatile memory apparatus according to claim 1, wherein said first information is validity management information indicative of validity of a storage area of said second information.

3. The nonvolatile memory apparatus according to claim 2, wherein when the nonvolatile memory is operated according to an instruction from the controller, said controller checks validity of a storage area of said second information on the basis of the validity management information read from the nonvolatile memory by performing the first reading operation and, when it is determined that the storage area is valid, performs the second reading operation to read the second information from the nonvolatile memory.

4. The nonvolatile memory apparatus according to claim 3, wherein said controller checks validity of a storage area of said second information on the basis of validity management information read from the nonvolatile memory by performing the first reading operation, when it is determined that the storage area is invalid, checks validity of the storage area of said second information on the basis of the validity management information read from the nonvolatile memory by performing the first reading operation on an alternative area of the storage area of said second information and, when the storage area is valid, performs the second reading operation to read the second information from the alternative area.

5. The nonvolatile memory apparatus according to claim 1,
wherein said nonvolatile memory cell has a threshold voltage included in one of four or more threshold voltage distributions according to information to be stored, and
wherein at the time of storing said first information into said nonvolatile memory cell, said nonvolatile memory uses a predetermined voltage between said threshold voltage distributions as a boundary, sets, as the threshold voltage of the nonvolatile memory, any of threshold voltage distributions of voltages higher than said predetermined voltage or threshold voltage distributions of voltages lower than said predetermined voltage, and compares said predetermined voltage with the threshold voltage of a nonvolatile memory cell in said first reading operation, thereby reading m-bit information.

6. The nonvolatile memory apparatus according to claim 5, wherein the threshold voltage of a nonvolatile memory cell in which said first information is stored is a voltage selected from a voltage in an upper-limit threshold voltage distribution and a voltage in a lower-limit threshold voltage distribution.

7. The nonvolatile memory apparatus according to claim 1,
wherein said controller can output second information read from the nonvolatile memory by said second reading operation to the outside, and can supply said second information input from the outside to the nonvolatile memory, and
wherein said nonvolatile memory has a memory buffer which can temporarily store second information read by said second reading operation before the second information is supplied to said controller and can temporarily store second information supplied from said controller before said second information is stored into said nonvolatile memory cell.

8. The nonvolatile memory apparatus according to claim 7, wherein said nonvolatile memory outputs first information by bypassing said memory buffer at the time of reading first information by said first reading operation.

9. The nonvolatile memory apparatus according to claim 8, wherein said first information includes validity management information indicative of validity of a storage area of said second information.

10. The nonvolatile memory apparatus according to claim 9, wherein when the nonvolatile memory is operated according to an instruction from the controller, said controller checks validity of a storage area of said second information on the basis of validity management information read from the nonvolatile memory by performing the first reading operation and, when it is determined that the storage area is valid, writes the second information of said memory buffer into a memory cell.

11. The nonvolatile memory apparatus according to claim 10, wherein said controller checks validity of a storage area of said second information on the basis of validity management information read from the nonvolatile memory by performing the first reading operation, when it is determined that the storage area is invalid, checks validity of the storage area of said second information on the basis of validity management information read from the nonvolatile memory by performing the first reading operation on an alternative area of the storage area of said second information and, when the storage area is valid, writes the second information in the memory buffer into a memory cell in the alternative area.

12. The nonvolatile memory apparatus according to claim 7, wherein said controller has a controller buffer for temporarily holding second information supplied from the outside and temporarily holding second information read from the nonvolatile memory and supplied.

13. The nonvolatile memory apparatus according to claim 12, wherein said controller supplies data from the controller buffer to the memory buffer, after that, stores the data in the memory buffer to a nonvolatile memory cell and, in parallel with the storing operation, can input another data from the outside into the controller buffer.

14. A nonvolatile memory apparatus comprising a nonvolatile memory and a controller,
wherein said nonvolatile memory has a plurality of nonvolatile memory cells each of which can be set in an information storing state included in one of four or more information storing states, and can perform a first reading operation of outputting information read from said nonvolatile memory cell which is set in said information storing state as information of m bits (m: integer of 1 or larger) and a second reading operation of outputting information read from said nonvolatile memory cell which is set in said information storing state as information of n bits (n: integer larger than m), and
wherein said controller performs the first reading operation to read first information from said nonvolatile memory and performs the second reading operation to read second information from said nonvolatile memory.

15. The nonvolatile memory apparatus according to claim 14, wherein an information storing state included in one of said four or more information storing states is a threshold voltage state included in one of four or more threshold voltage distributions of a nonvolatile memory cell.

16. The nonvolatile memory apparatus according to claim 15, wherein at the time of storing said first information into said nonvolatile memory cell, said nonvolatile memory sets, as a threshold voltage of the nonvolatile memory cell, a voltage selected from a voltage in said threshold voltage distribution of the upper limit and a voltage in said threshold voltage distribution of the lower limit.

17. The nonvolatile memory apparatus according to claim 16,
wherein said nonvolatile memory has a memory buffer which can hold second information read as n-bit information from each of a plurality of nonvolatile memory cells by said second reading operation, supply the second information to the controller, hold second information supplied from said controller, and set one nonvolatile memory cell every n bits, at a threshold voltage included in one of four threshold voltage distributions, and
wherein the first information read as m-bit information from each of the plurality of nonvolatile memory cells by said first reading operation is output to said controller while bypassing said memory buffer.
